(19) United States
(12) Patent Application Publication
(10) Pub. No.: US 2012/0025175 A1
(43) Pub. Date: Feb. 2, 2012

(54) DIODE BASED ON ORGANIC MATERIAL

(75) Inventors: Rene Wirtz, Stuttgart (DE); Nikolaus Knorr, Stuttgart (DE); Silvia Rosselli, Mannheim (DE); Gabriele Nelles, Stuttgart (DE)

(73) Assignee: Sony Corporation, Tokyo (JP)

(21) Appl. No.: 13/116,690

(22) Filed: May 26, 2011

(30) Foreign Application Priority Data
Jul. 28, 2010 (EP) 10007874.0

(51) Int. Cl. H01L 51/10; H01L 51/40

(52) U.S. Cl. 257/40; 438/99; 257/E51.008

(57) ABSTRACT

Semiconductor device, comprising a substrate with a first electrode and having a layer of organic material deposited over the substrate and the first electrode; and a second electrode deposited over the layer of organic material, wherein the second electrode comprises a dielectric layer that is separated from the layer of organic material by the material of the second electrode.

The invention relates to a semiconductor device and in particular to a diode based on organic material.

One of the key characteristics of any diode is the rectification ratio, i.e. the ratio of the current in conducting direction versus the current in blocking direction at the same voltage of opposite polarity.

The rectification properties of a diode such as a Schottky-type diode are of particular importance for passive, i.e. non-amplified semiconductor devices having a cross-bar architecture which is currently the most favored architecture for electronics devices that are based on organic materials. In a passive device with an appropriate number and density of cross points arranged in a cross-bar architecture, every diode provided at a cross point of the array must have a current rectifying functionality to assure a non-ambiguous addressing of all individual diodes. Without a sufficient capability of current rectifying the cross talk between the different lines and columns of the cross-bar architecture will be too large and detrimentally influence the correct function of the device.

For a 10 Mb cross bar device, Scott et al. calculated that each cross-point needs a rectification ratio in excess of 1:10^{8 [}1]. This magnitude of rectification ratio is difficult to achieve with standard type diodes commonly used in organic electronic devices. Standard organic material diodes are based on a Schottky-type barrier that is formed between a semiconducting organic material and a metal, whereby the work function of the metal differs significantly from the highest occupied molecular orbital (HOMO) for n-type conduction organic material or the lowest unoccupied molecular orbital (LUMO) for a p-type conduction organic material.

Lee et al. demonstrated that an ultrathin MgO layer between CoFeB and Ge modulated the Schottky barrier heights and contact resistances of spin diodes [2]. Although the MgO layer increased the current rectification ratio of the Schottky diode, it was observed that the deposition of the MgO layer between the semiconductor and the metal can lead to a depinning of the Fermi-level, thereby increasing the Schottky barrier height.

Therefore, it is the object of the present invention to provide a diode that is based on an organic material and that has an enhanced rectification ratio compared to conventional organic material based diodes and which has a structure that permits a reduction of detrimental effects on the organic material during the fabrication of the diode.

This object is achieved with a semiconductor device comprising the features of claim 1 and by a method of forming a semiconductor device comprising the features of claim 8.

The semiconductor device of the present invention comprises a substrate with a first electrode having a layer of organic material deposited over the substrate and electrode, and a second electrode deposited over the layer of organic material, wherein the second electrode comprises a dielectric layer that is separated from the layer of organic material by the material of the second electrode.

By providing a dielectric layer between the organic material and at least a part of the second electrode, the rectification ratio of the diode can be significantly enhanced by one or several orders of magnitude. Since the dielectric layer is not in direct contact with the organic material but is separated from the organic material by a metal layer, a damaging of the organic material can be avoided during the deposition of the dielectric material which can be caused by the etching effect of a plasma that is used for the deposition of the dielectric layer or by a diffusion of the material of the dielectric layer into the organic material. In principle, any dielectric material can be used for the dielectric layer. Examples of dielectric material comprise silicon dioxide (SiO₂), silicon monoxide (SiO), silicon nitride (SiN), silicon oxynitride (SiON), TEOS, FTEOS without being limited to these materials. Regarding the organic material any semiconducting organic material will work. However, the HOMO/LUMO levels should be matched to the electrode material in such a way as to yield an effective diode behaviour of the device. Examples of organic semiconducting material comprise polythiophenes, polyparaphenylenes, polypyrrole, polyaniline, polyacetylene, anthracene, pentacene without being limited to these materials.

According to a preferred embodiment, the second electrode comprises three layers, wherein the dielectric layer is sandwiched between two layers of metal. The metal can be the same in both metal layers. According to another embodiment, the two layers of metal consist of different materials. Suitable metals comprise gold (Au), copper (Cu), aluminum (Al), platinun (Pt), and others as well as alloys thereof. The second electrode or the upper layer of metal may serve as a top electrode of the diode providing an electric contact to the diode.

According to a further preferred embodiment, the dielectric layer comprises a thickness ranging between 0.5 nm and 10 nm, including exemplifying thicknesses of 0.5 nm, 1.0 nm, 2.5 nm, 5.0 nm, 7.5 nm and 10 nm. Preferably, the thickness of the dielectric layer is selected to permit a tunneling of electrons through it, but thick enough as to prevent an electric breakthrough through the dielectric layer. Preferably, the dielectric layer does not have any rectifying properties itself but acts as a tunneling barrier. This results in the increase of the rectification ratio of the device.

According to still another embodiment of the invention, the device comprises an insulating layer between the substrate and the first electrode or the layer of organic material. The insulating layer can be of silicon dioxide (SiO₂). However, other dielectric materials may also be suitable. The insulating layer can be thermally grown or can be deposited by a deposition process such as CVD. According to another embodiment a substrate formed of an insulating material may be provided instead of a substrate provided with an insulating layer.

According to yet another embodiment, the device comprises the first electrode between the substrate or the insulating layer on the substrate and the layer of organic material. The first electrode may serve as a bottom electrode of the device. According to yet another embodiment, the first electrode and the second electrode each comprise a stripe-shaped structure and cross each other preferably with an angle of 90°. According to another embodiment also the first electrode may be composed of several layers of materials and may comprise three layers as described for one embodiment of the second electrode above.

According to still another embodiment the device comprises several first electrodes having a stripe shape structure extending in parallel, several second electrodes having a stripe shape structure extending in parallel, and several diodes each comprising a layer of organic material at the points where the first and second electrodes are crossing each other. Hence, an array comprising several stripe-shaped first electrodes several stripe-shaped second electrodes and diodes may be fabricated simultaneously on a single substrate in a same process.

The method according to the invention of forming a semiconductor device comprises steps of forming such as depositing a layer of organic material over a substrate with a first electrode, and forming such as depositing a second electrode over the layer of organic material, wherein the electrode comprises a dielectric layer that is formed over at least a part of the second electrode so that it is separated from the layer of organic material by at least a part of the material of the second electrode.

One or several additional layers may also be provided between the substrate and the layer of organic material. Similarly, the second electrode may directly be formed or deposited on the layer of organic material, but one or several other layers may also be provided between the layer of organic material and the second electrode.

By the method according to the invention a diode based on an organic material having an enhanced rectification ratio is formed. The method according to the invention may form a part of a process of fabricating a device having several highly integrated diodes based on an organic material in a cross-bar architecture. The cross talk between neighboring diodes and electric lines is reduced compared to conventional diodes.

According to a preferred embodiment of the method, the depositing of the second electrode further comprises steps of depositing a layer of a first metal, subsequently depositing the dielectric layer on top of the layer of the first metal and finally depositing a layer of a second metal on top of the first dielectric layer. Accordingly, a three-layer electrode is provided, having the advantage that the dielectric layer is not formed directly on the organic semiconductor material. Therefore, a damaging of the organic layer during the deposition of the dielectric layer by an undesirable etching by the plasma used for the deposition such as in a sputtering process can be avoided. Furthermore, a diffusion of molecules of the dielectric layer into the organic material can be avoided or at least minimized due to the separation of the organic layer from the dielectric layer by the metal layer of the second electrode.

According to a further embodiment, the method includes depositing an insulating layer such as SiO₂ on the substrate before depositing the organic material. Instead of providing an insulating layer on the substrate, an insulating substrate may be used. The insulating substrate can be made of a flexible material.

According to still another embodiment, the method comprises forming or depositing a first electrode layer on the insulating layer or on the substrate before forming or depositing the layer of organic material. The first electrode layer may serve as a bottom electrode of the diode device.

Furthermore, according to yet another embodiment, the first electrode and the second electrode each comprise a stripe shape and cross each other at 90°. Hence a deposition of several stripe shaped first and second electrodes may result in a cross-bar array comprising several diodes. For the deposition of the material of the first and second electrodes in the form of a stripe may be achieved with a corresponding photo resist mask. However, other suitable techniques can be used as well.

According to still another embodiment the method includes a forming of several first electrodes having a stripe shape structure extending in parallel, a forming of several second electrodes having a stripe shape structure extending in parallel, and a forming of several diodes each comprising a layer of organic material at the points where the first and second electrodes are crossing each other in a same process on the substrate. Hence, an array of diodes having a cross-bar architecture is formed.

Further embodiments, features and advantages of the invention will result from the following description of an exemplifying embodiment of the invention with reference to the drawing in which

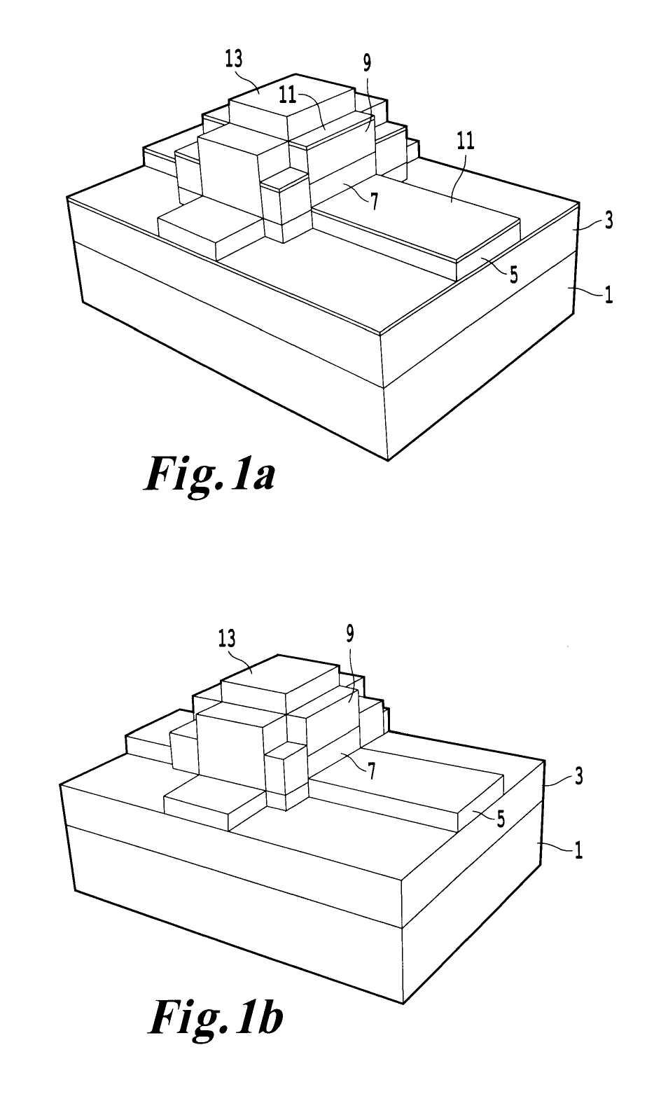

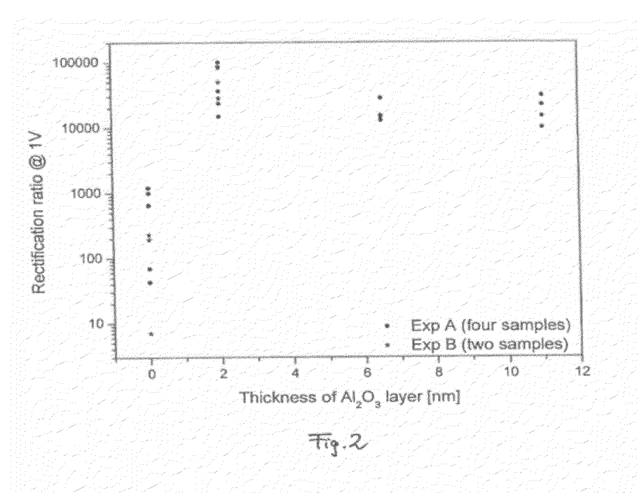

FIG. 1a shows a diode device according to one embodiment of the invention in a perspective view;

FIG. 1b shows the same diode as shown in FIG. 1a without the dielectric layer of the electrode;

FIG. 2 shows the measured rectification ratios of several samples comprising the structure shown in FIG. 1a but having varying thicknesses of their dielectric layer as a function of the layer thickness;

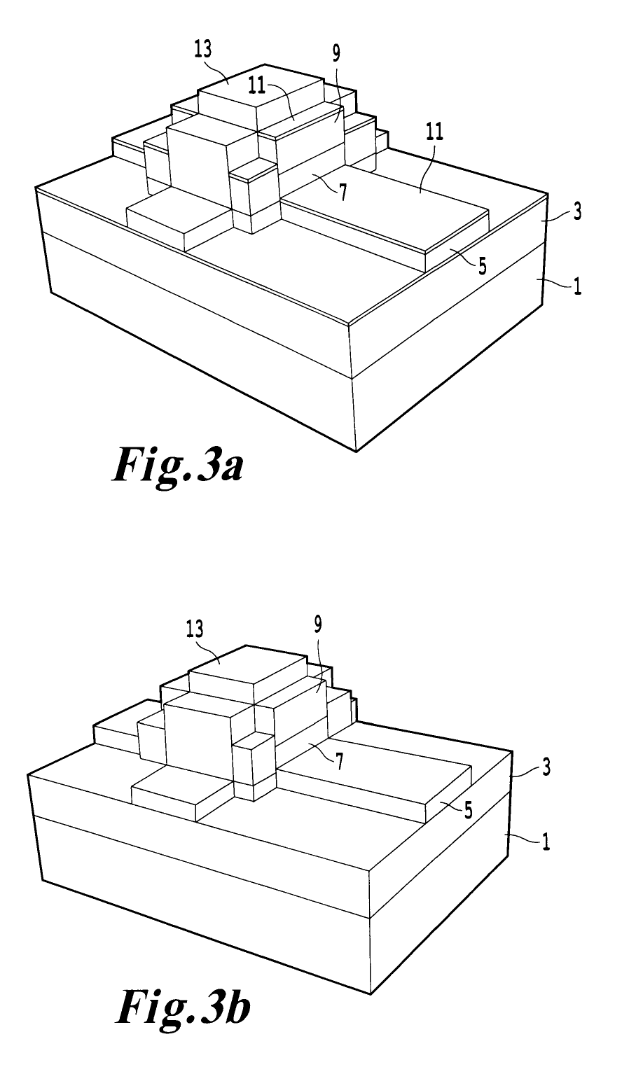

FIG. 3a shows an alternative diode comprising a similar structure as the diode shown in FIG. 1a but having other materials used for the electrode; and

FIG. 3b shows the same diode as shown in FIG. 3a without the dielectric layer of the electrode;

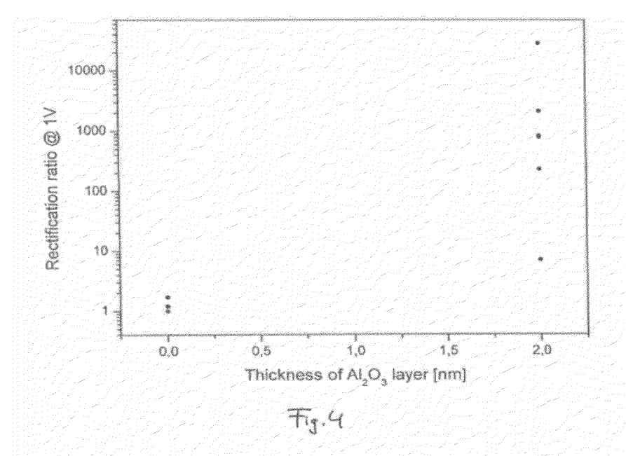

FIG. 4 shows the measured rectification ratios of several samples comprising the structure shown in FIG. 3a but having varying thicknesses of their dielectric layer as a function of the layer thickness;

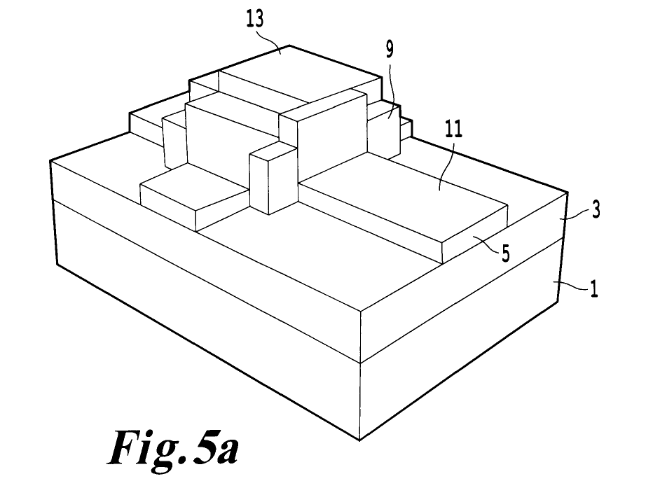

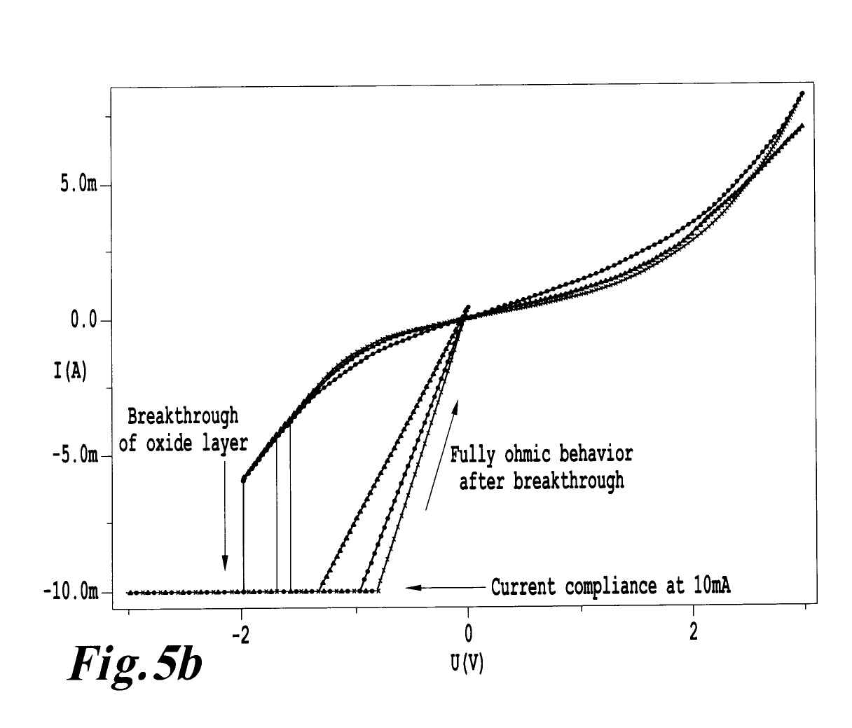

FIG. 5a shows a device corresponding to the devices shown in FIGS. 1a and 3a, however, without the organic semiconducting material; and

FIG. 5b shows I-V measurements obtained with the device shown in FIG. 5a.

In the following, a diode according to an embodiment of the invention is described with reference to FIGS. 1a to 2.

The diode device according to the embodiment shown in FIG. 1a comprises a silicon substrate 1 on which a dielectric layer 3 of silicon dioxide (SiO₂) is grown thermally or by a deposition process (CVD) in order to render the substrate surface electrically insulating. On top of the dielectric layer 3 a stripe-shaped electrode layer 5 of aluminum (Al) is deposited. Preferably, the stripe-shaped electrode layer 5 is deposited by evaporation on the substrate 1 including the dielectric layer 3 using a photo resist mask that is subsequently removed, wherein only the electrode layer 5 remains. The stripe-shaped electrode layer 5 may serve as bottom electrode of the diode device. On top of the electrode layer 5, a layer 7 of organic material such as poly (3-hexylthiophene) (P3HT) is deposited. On top of the layer 7 of organic material, a metal layer 9 such as gold (Au) is deposited using a shadow mask comprising a substantially rectangular or square shape partly overlapping the stripe-shaped electrode layer 5. Subsequently, a dielectric layer 11 of aluminum oxide (Al₃O₂) is deposited which covers also the sides of the bottom electrode layer 5, of the layer 7 of organic material and of the metal layer 9, since the dielectric layer 11 of aluminum oxide is grown non-directionally by sputter deposition. However, in FIG. 1a the sides of the bottom electrode layer 5, of the layer 7 of organic material and of the metal layer 9 is not shown covered in order not to obscure the layer structure of the diode. When using a plasma deposition technique to deposit the dielectric layer 11 (e.g. a sputter-deposition in an Ar-atmosphere) the metal layer 9 also acts as an etch mask as it protects the underlying layer 7 of organic semiconductor material from the plasma. Depending on the exact properties of the interaction between the plasma and the layer 7 of organic semiconductor material, the plasma can etch away all the not-protected organic semiconductor that is not covered by metal layer 9.

Finally, copper is deposited through a stripe-shaped shadow mask to form a metal layer 13 of copper (Cu) on the structure. The stripe-shaped metal layer 13 of copper (Cu) extends perpendicular to the electrode layer 5 of the bottom electrode. In FIG. 1a only a portion of the prepared sample is shown which comprises a single diode only. However, by the process an entire cross-bar array comprising several stripe-shaped bottom electrodes extending parallel to each other and several stripe-shaped top electrodes extending parallel to each other as well as a plurality of diodes at the crossing points of the bottom and top electrodes are formed.

The top electrode of each diode comprises a three-layered structure (metal, dielectric, metal), wherein the rectification ratio of the diode is enhanced by several orders of magnitude due to the dielectric layer.

The details of the preparation process of the sample shown in FIG. 1 are summarized in Annex 1. FIG. 1b shows a diode device which is similar to the device of FIG. 1a. However, the dielectric layer 11 of aluminum oxide (Al₃O₂) has been omitted.

In FIG. 2 the measured rectification ratios of devices all having a structure as shown in FIGS. 1a, 1b but different thicknesses of the dielectric layer 11 of aluminum oxide (Al₃O₂) are presented as a function of the thickness of the dielectric layer. As results from FIG. 2, an increase of the thickness of the Al₂O₃ layer from zero nm (a sample having no Al₂O₃ layer as shown in FIG. 1b) to 2.0 nm results in an increase of the rectification ratio by a factor of approximately between 10 and 100. The values of the ratio for samples with no Al₂O₃ layer vary between approximately 5 and 1500, while the values of the ratio for samples with a Al₂O₃ layer having a thickness of 2.0 nm vary between approximately 15×10³ and 1×10⁵. A further increase of the thickness of the Al₂O₃ layer to approximately 6.6 or 11.0 nm does not result in any significant change of the rectification ratio. Rather, a slight decrease of the rectification ratio can be observed which may be related to a reduced tunneling probability with increasing thickness of the thickness of the Al₂O₃ layer. The measurements denoted by dots and stars refer to two different samples (A and B). Each sample has been measure four and two times, respectively, under the same conditions but at different locations on the sample.

The sample shown in FIG. 3a essentially has the same structure as the sample shown in FIG. 1a. The reference numerals in FIG. 3a denote the same elements of the sample. However, some of the materials of the layers have been varied. Instead of using aluminum for the bottom electrode layer 5, gold has been used, and instead of gold aluminum has been used for the layer 9 of the top electrode. FIG. 3b shows the same device structure as FIG. 3a with the exception that the dielectric layer 11 was omitted.

The measurements of the rectification ratio carried out with the device shown in FIG. 3a and shown in FIG. 4 indicate an increase of the rectification ratio by a factor of between approximately five and 3000 for an increase of thickness of the Al₂O₃ layer from zero (no layer) to 2.0 nm. The values of the ratio for samples with no Al₂O₃ layer vary between approximately 1 and 2, while the values of the ratio for samples with a Al₂O₃ layer having a thickness of 2.0 nm vary between approximately 7.5 and 3×10⁴.

The details of the preparation process of the sample shown in FIG. 3a are summarized in Annex 2. FIG. 3b shows a diode device which is similar to the device of FIG. 3a. However, the dielectric layer 11 of aluminum oxide (Al₃O₂) has been omitted.

FIG. 5a shows a control device which corresponds to the devices shown in FIGS. 1a and 3a with the exception that the layer 7 of organic material has been omitted. The I-U-measurement shown in FIG. 5b indicates that the layer 11 of the dielectric material acts as a tunneling barrier but does not have any rectifying properties itself. As is visible in the graph of FIG. 5b, the current (I) as a function of the voltage (U) shows the characteristics of a tunneling current in a voltage range between −1.5 V and 3V. At larger negative voltages below −1.5V, a breakthrough is reached where the current abruptly increases. Reducing the voltage after a breakthrough of the device, an ohmic behavior of the device is observed. Hence, the current linearly increases when the voltage is reduced. This indicates that the dielectric layer 3 in the electrode stack acts as a tunneling barrier only but does not have any rectifying properties itself.

Various modifications may provided to the embodiments without leaving the scope of the invention.

### Annex 1:

Layer stack: A) Al/P3HT/Au/Al₂O₃/Cu-stack (FIG. 1a): (two controls: C): no Al₂O₃ (FIG. 1b), D): no P3HT (FIG. 5a))
Clean Si/SiO₂-substrates
Evaporate bottom electrodes: 50 nm Al (lines and spaces)
Prepare P3HT: P3HTregio-regular in 1,2,4-trichlorobenzene (30 mg/ml)
Spin-on: Spin on P3HT (A, C only)

### Bake out

Clean bond pads with trichlorobenzene
Bottom layer of top electrodes. 50 nm Au (squares)
Sputter deposition of Al₂O₃: roughly 2 nm (A, D only)
Comment: The visible P3HT was completely etched away by the Ar-plasma. However, it should still be intact under the Au-squares.
Top electrodes: 50 nm Cu (lines and spaces)
Cut 12 single junctions each and bond into sample holders

### Annex 2:

Layer stack: Cr/Au/P3HTr.-regular/Al/Al₂O₃/Cu (FIG. 3a) (plus one control, without Al₂O₃ (FIG. 3b))
Clean substrates:
Bottom electrodes: 3 nmCr/50 nm Au (lines and spaces)
Prepare P3HT: P3HTregio-regular 1,2,4-trichlorobenzene (30 mg/ml)

### Spin-on

### Bake

Clean bond pads with trichlorobenzene
Middle electrodes: 50 nm Al (squares)
Sputter deposition of Al₂O₃: roughly 2 nm (not for control)
Top electrodes: 50 nm Cu (lines and spaces)
Cut out 12 single junctions, bond into packages

### REFERENCES

[1] “Nonvolatile Memory Elements Based on Organic Materials”, J. Campbell Scott and Luisa D. Bozano, Advanced Materials 2007, 19, 1452-1463;
[2]: “The influence of Fermi level pinning/depinning on the Schottky barrier height and contact resistance in Ge/CoFeB and Ge/MgO/CoFeB structures”; D Lee et al.; Applied Physics Letters 96, 052514 (2010)

1. Semiconductor device, comprising:
a substrate (1) with a first electrode (5) and having a layer of organic material (7) deposited over the substrate (1) and the first electrode (5); and a second electrode deposited over the layer of organic material (7), wherein the second electrode comprises a dielectric layer (11) that is separated from the layer of organic material (7) by the material of the second electrode.

2. Semiconductor device of claim 1, wherein the second electrode comprises three layers, wherein the dielectric layer (11) is sandwiched between two layers (9, 13) of metal.

3. Semiconductor device of claim 1 or 2, wherein the two layers (9, 13) of metal consist of different metals.

4. Semiconductor device of one of claims 1 to 3, wherein the first dielectric layer (11) comprises a thickness in the range between 0.5 and 10 nm, wherein the thickness permits a tunnelling of electrons through it and prevents a current breakthrough through it.

5. Semiconductor device of one of claims 1 to 4, further comprising an insulating layer (3) between the substrate (1) and the layer of organic material (7).

6. Semiconductor device of claims 1 to 5, wherein the first electrode (5) and the second electrode each comprise a stripe shape structure and cross each other.

7. Semiconductor device of one of claims 1 to 6, further comprising several first electrodes (5) having a stripe shape structure extending in parallel, several second electrodes having a stripe shape structure extending in parallel, and several diodes each comprising a layer of organic material (7) at the points where the first and second electrodes are crossing each other.

8. Method of forming a semiconductor device, comprising:
forming a layer of organic material (7) over a substrate (1) with a first electrode (5), and forming a second electrode over the layer of organic material (7), wherein the second electrode comprises a dielectric layer (11) that is formed over at least a part of the second electrode so that it is separated from the layer of organic material (7) by at least a part of the material of the second electrode.

9. Method of claim 8, wherein forming the second electrode further comprises forming a layer of a first metal, forming the dielectric layer (11) on top of the layer of the first metal, and forming layer of a second metal on top of the first dielectric layer (11).

10. Method of claim 8 or 9, further comprising forming an insulating layer (3) on the substrate (1).

11. Method of one of claims 8 to 10, further comprising forming the first electrode (5) and the second electrode with a stripe shape and such that they cross each other forming an array of crossbars.

12. Method of one of claims 8 to 11, including forming several first electrodes (5) having a stripe shape structure extending in parallel, several second electrodes having a stripe shape structure extending in parallel, and several diodes each comprising a layer of organic material (7) at the points where the first and second electrodes are crossing each other in a same process on the substrate.
